(19) United States
(12) Patent Application Publication
(10) Pub. No.: US 2013/0146451 A1
(43) Pub. Date: Jun. 13, 2013

(54) Magnetic Confinement and Directionally Driven Ionized Sputtered Films For Combinatorial Processing

(71) Applicant: Kent Child, Dublin, CA (US)

(72) Inventor: Kent Child, Dublin, CA (US)

(73) Assignee: Intermolecular, Inc., San Jose, CA (US)

(21) Appl. No.: 13/313,275

(22) Filed: Dec. 7, 2011

(51) Int. Cl. C23C 14/35; C23C 14/46

(52) U.S. Cl. 204/298.04; 204/298.16

(57) ABSTRACT

A combinatorial processing chamber having an integrated magnetic confinement system is described herein. The chamber comprises source magnetic confinement assemblies that are configured to shape ion beams produced by associated sputter sources. The chamber further comprises magnetic confinement assemblies that are configured to drive a combined ion beam onto an exposed surface of the substrate to combinatorial process regions of the substrate.

### FIELD OF INVENTION

The embodiments relate to a sputter deposition tool that is configured to shape an ion beam.

### BACKGROUND

Combinatorial processing may refer to various techniques used to vary characteristics of the processes applied to multiple regions of a substrate in serial, parallel or parallel-serial fashion. Combinatorial processing may be used to test and compare multiple and various processing techniques. The processing techniques may be validated, and those techniques that are useful may be applied to, for example, different substrates or full-substrate processing.

In a combinatorial processing system, ionized sputtered films may be deposited on a particular localized area on a wafer or substrate. However, when performing site isolated spot deposition in the combinatorial processing system, the ion beams delivering the films may not reach or bombard the localized area on the substrate uniformly, thereby leading to inadequate deposition thereon. In addition, the ion beams can become unfocussed over the travel distance from the sputter source to the substrate.

Thus, what is needed is an ionization process that performs an adequate deposition of ionized sputtered films on a substrate during combinatorial processing.

### BRIEF DESCRIPTION OF DRAWINGS

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system in accordance with some embodiments of the invention

FIG. 4 is a simplified schematic diagram illustrating a sputter chamber configured to perform combinatorial processing and full substrate processing in accordance with some embodiments of the invention.

FIG. 5 is a diagram illustrating a combinatorial processing chamber having an integrated magnetic confinement system in accordance with some embodiments of the invention

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

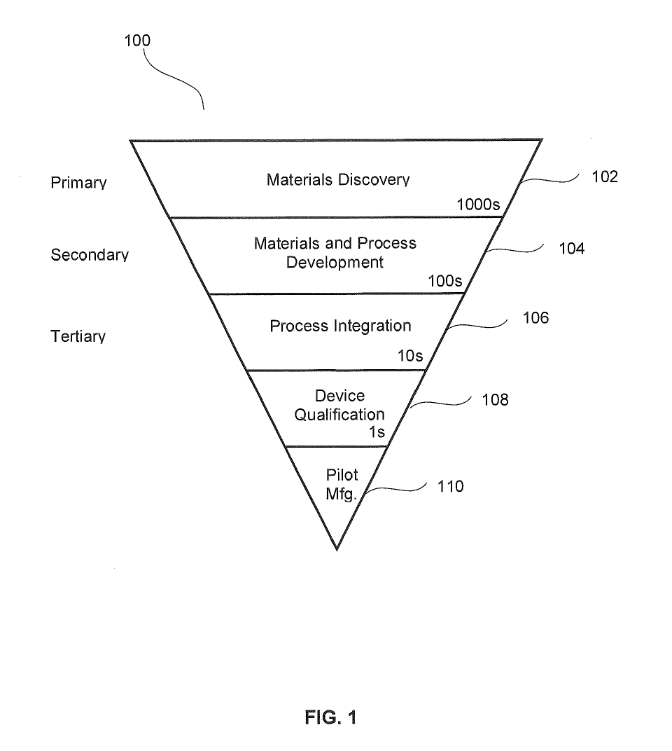

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

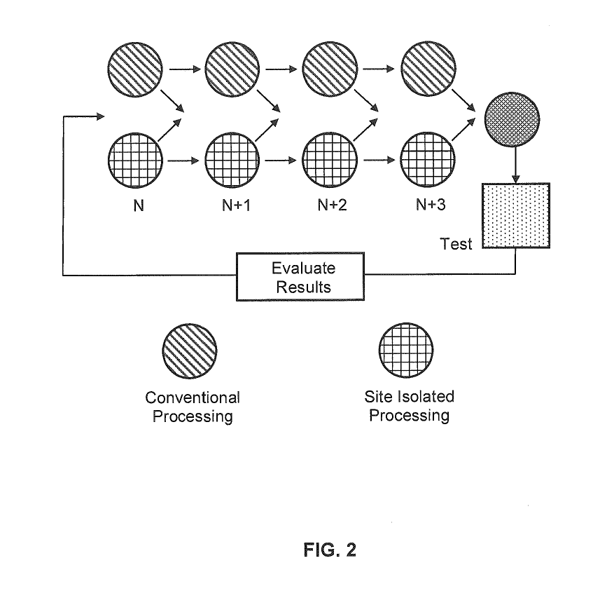

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

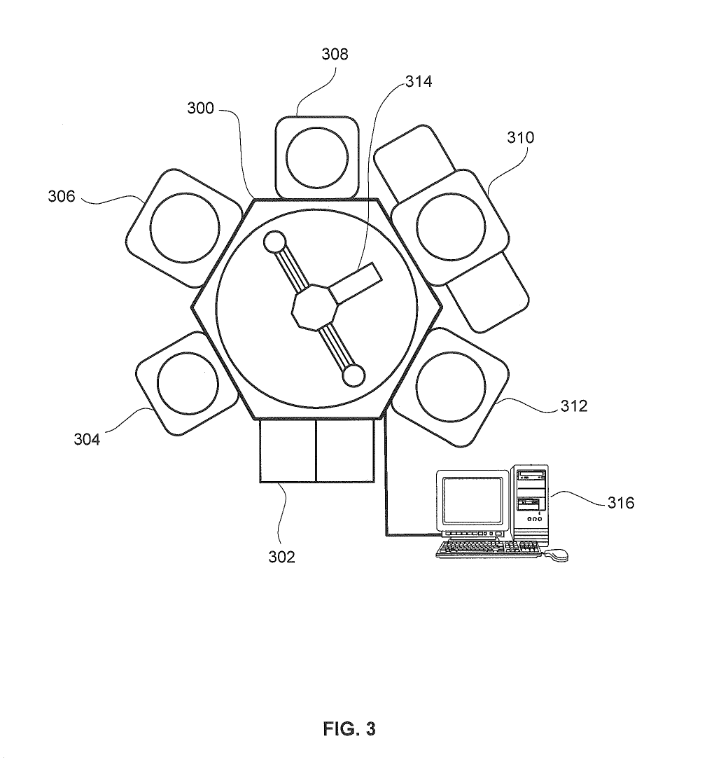

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

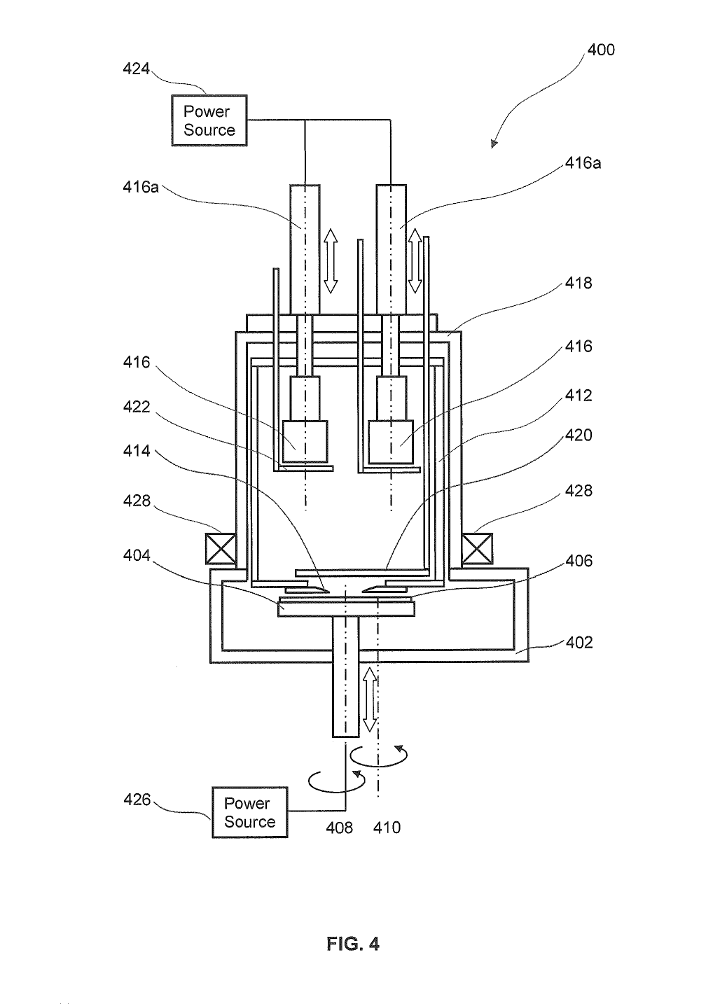

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424. Further details of the power sources and their operation may be found in U.S. patent application Ser. No. ______ entitled “High Metal Ionization Sputter Gun” filed on Nov. ______, 2011 with internal docket number (IM0281) and is herein incorporated by reference.

Substrate 406 may be a conventional round 200 mm, 300 mm, or any other larger or smaller substrate/wafer size. In other embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired. It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in another embodiment. In yet another embodiment, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments.

Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes auxiliary magnet 428 disposed around an external periphery of the chamber. The auxiliary magnet 428 is located in a region defined between the bottom surface of sputter guns 416 and a top surface of substrate 406. Magnet 428 may be either a permanent magnet or an electromagnet. It should be appreciated that magnet 428 is utilized to provide more uniform bombardment of Argon ions and electrons to the substrate in some embodiments.

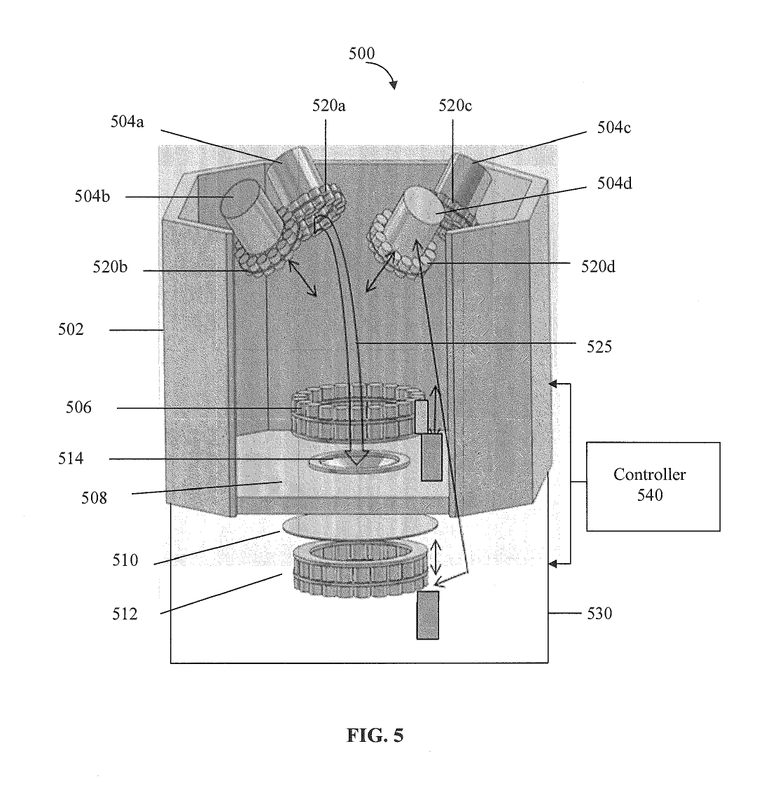

FIG. 5 is a diagram illustrating a combinatorial processing chamber 500 having an integrated magnetic confinement system in accordance with some embodiments of the invention. Chamber 500 may be an Ultra High Vacuum (UHV) sputtering chamber in some embodiments. Chamber 500 includes a bottom enclosure 530 disposed under upper enclosure 502. Upper enclosure 502 confines a plasma generated therein. Upper enclosure 502 has an enclosure bottom 508 with a bottom aperture 514. Bottom aperture 514 includes an aperture central axis. Bottom aperture 514 is located over a substrate support 510. Substrate support 510 may incorporate the features noted above for substrate support 404 of FIG. 4. Within bottom enclosure 530, substrate support 510 is configured to hold a wafer or substrate disposed thereon and can be any known substrate support, including but not limited to a vacuum chuck, electrostatic chuck or other known mechanisms. A surface of the substrate is exposed through bottom aperture 514 for deposition or other suitable semiconductor processing operations. Substrate support 510 is capable of both rotating around a central axis of the substrate (referred to as “rotation” axis), and rotating around an exterior axis (referred to as “revolution” axis) that is offset from the central axis of the substrate support. Other substrate supports, such as an XY table, can also be used for site-isolated deposition in some embodiments. In addition, substrate support 510 may move in a vertical direction along the central axis. It should be appreciated that the rotation and movement in the vertical direction may be achieved through known drive mechanisms which include magnetic drives, linear drives, worm screws, lead screws, a differentially pumped rotary feed through drive, etc. A power source similar to power source 226 of FIG. 4 provides a bias power to substrate support 510 and the substrate disposed thereon, and produces a negative bias voltage on the substrate. In some embodiments, the power source provides a radio frequency (RF) power sufficient to take advantage of the high metal ionization to improve step coverage of vias and trenches of patterned wafers. In other embodiments, the RF power supplied by the power source is pulsed and synchronized with a pulsed power from a separate power source (similar to power source 224 of FIG. 4) that provides power to sputter sources 504a, 504b, 504c and 504d.

Chamber 500 includes a first magnetic confinement assembly 506 having a central axis. In some embodiments, the central axis of first magnetic confinement assembly 506 is common to the axis of bottom aperture 514. The first magnetic confinement assembly 506 is positioned within upper enclosure 502 and above bottom aperture 514. First magnetic confinement assembly 506 may be arranged to move in a vertical direction along an axis of bottom aperture 514. Chamber 500 includes a second magnetic confinement assembly 512 having a central axis common to the axis of bottom aperture 514 in some embodiments. The second magnetic confinement assembly 512 may be positioned below substrate support 510, i.e., outside the plasma region. The second magnetic confinement assembly 512 may be arranged to move in a vertical direction along an axis of bottom aperture 514. The first magnetic confinement assembly 506 and the second magnetic confinement assembly 512 may be attached to the upper enclosure 502 in a known manner, such as a post or rail and the magnetic confinement assemblies may be driven along the post or rail through a drive capable of functioning under the high temperature and high vacuum processing conditions, such as magnetic drives, linear drives, worm screws, lead screws, a differentially pumped rotary feed through drive, etc.

In some embodiments, the first and/or second magnetic confinement assemblies may include electromagnets. The electromagnets may be made of copper and/or other electromagnetic materials. In some embodiments, the first and/or second aperture magnetic confinement assemblies may include permanent magnets. The permanent magnets may be made of neodymium and/or other known magnetic materials. Where electromagnets are employed, it should be appreciated that the cooling system for the substrate support 510 or the sputter sources may be integrated with the magnetic assemblies in some embodiments. It should be appreciated that electromagnets enable a user to tune the process as the current delivered to the electromagnet may be adjusted to adjust the magnetic field. Thus, in some embodiments, a process may be tuned with an electromagnet and permanent magnets may be utilized thereafter once the optimum settings are identified.

Chamber 500 includes a plurality of sputter sources 504a, 504b, 504c, and 504d (noted hereinafter as sputter source(s) 504). Sputter sources 504 may be located above bottom aperture 514 and first magnetic confinement assembly 506. In some embodiments, each sputter source 504 has a sputter source axis and is movable along the sputter source axis or rotatable around the sputter source axis. Each sputter source 504 may be arranged in a tilted configuration. It should be appreciated that the arrival rate of the ion beams from the sputter source to the surface of the substrate may be non-uniform due to the sputter source surface having different elevations from the substrate surface. In some processing operations, uniform arrival of the ion beam to the surface of the substrate is important, e.g., high dielectric metal gate processing (HKMG). It should be appreciated that the diameter of the sputter sources 504 may be smaller than the substrate, as opposed to sputter source diameters for conventional full wafer processing. In some embodiments, each or at least one sputter source 504 may have a respective source magnetic confinement assembly 520a, 520b, 520c, and 520d (noted hereinafter as source magnetic confinement assembly/assemblies 520) associated therewith. For example, sputter source 504a may have source magnetic confinement assembly 520a associated therewith, sputter source 504b may have source magnetic confinement assembly 520b associated therewith, sputter source 504c may have source magnetic confinement assembly 520c associated therewith, and sputter source 504d may have source magnetic confinement assembly 520d associated therewith. Each sputter source 504 may be supported within the upper enclosure 502 in a known manner, or as illustrated through application Ser. No. 12/027,980 entitled “Combinatorial Process System” filed on Feb. 7, 2008 and claiming priority to U.S. Provisional Application No. 60/969,955 filed on Sep. 5, 2007, both of which are herein incorporated by reference.

In some embodiments, the source magnetic confinement assemblies 520 may be rigidly affixed to the frame of sputter sources 504. In some embodiments, the source magnetic confinement assemblies 520 may include permanent magnets. In alternative embodiments, the source magnetic confinement assemblies 520 may include electromagnets. Where electromagnets are included, the cooling for the electromagnets may be provided through the cooling system for the sputter sources 504. The source magnetic confinement assemblies are moveably affixed to the ground shield of the target for each sputter source 504 in some embodiments. Thus, the confinement assemblies 520 are external to the plasma or outside the plasma loop in these embodiments. Source magnetic confinement assemblies 520 may be driven along an axis of each sputter source 504 by a suitable drive coupled to the magnetic confinement assemblies, such as, magnetic drives, linear drives, worm screws, lead screws, a differentially pumped rotary feed through drive, etc.

In summary, each source magnetic confinement assembly 520 and its associated sputter source 504 may be configured to move relative to one another along the associated respective sputter source axis. The first magnetic confinement assembly 506 is movable vertically with respect to an axis of bottom aperture 514. The second magnetic confinement assembly 512 is also movable vertically with respect to an axis of bottom aperture 514. It should be appreciated that the source and first and second magnetic confinement assemblies are movable (i.e., position is adjustable) for process optimization and combinatorial processing of different sputter targets and films. The movement of the source and first and second magnetic confinement assemblies may be achieved through known drive mechanisms which include, linear motor drives, and/or other mechanisms. In some embodiments, the drive mechanism responsible for movement of the source and first and second magnetic confinement assemblies may be situated inside chamber 500. In some embodiments, the drive mechanism responsible for movement of the source and first and second magnetic confinement assemblies may be situated external to chamber 500. In some embodiments, the movement of the source and first and second magnetic confinement assemblies may be achieved through known pneumatic drive mechanisms. It should be appreciate that while each of the source magnetic confinement assemblies and the first and second magnetic confinement assemblies are illustrated as annular rings, this is not meant to be limiting as alternative shapes and configurations may be integrated with the embodiments.

Tilt angles and position of the sputter sources 504 are optimized to ensure uniform arrival rates of the ion beams produced by the sputter sources 504 at the first aperture magnetic confinement assembly 506. Each source magnetic confinement assembly 520 may be configured to shape an ion beam produced by its associated sputter source 504. Each source magnetic confinement assembly 520 may be configured to gear/direct the ion beams towards the first aperture magnetic confinement assembly 506. The position and/or magnetic field intensity of the source magnetic confinement assemblies 520 may be optimized to ensure that the ion beams are directed at an appropriate angle so as to converge into an area above first magnetic confinement assembly 506 and/or bottom aperture 514, thereby forming a combined ion beam 525. That is, the source magnetic confinement assemblies 520 are configured to collectively shape a combined ion beam 525 produced by the sputter sources 504 such that the combined ion beam 525 is received at first magnetic confinement assembly 506.

The first and second magnetic confinement assemblies 506 and 512 may be configured to drive the combined ion beam 525 onto an exposed surface of the substrate via bottom aperture 514 to combinatorial process regions of the substrate. The position and/or magnetic field intensity of the first and second magnetic confinement assemblies 506, 512 may be optimized to ensure that the combined ion beam 525 is directed to a particular region of the substrate for purposes of spot deposition in combinatorial processing processes. The magnetic fields generated by the source magnetic confinement assemblies 520 and the first and second magnetic confinement assemblies 506, 512 may shape and drive the ion beam and/or combined ion beam for better utilization of sputtered material.

A controller 540 is configured to control the tilt angles and/or position of sputter sources 504, the position and/or magnetic field intensity of the source magnetic confinement assemblies 520 in some embodiments. Controller 540 may also control the position and/or magnetic field intensity of the first and second magnetic confinement assemblies 506 and 512. Based on information about a product or process for a particular location of the substrate supported by the substrate support 510, controller 540 may provide one or more control signals to the sputter sources 504, the source magnetic confinement assemblies 520, and/or first and second magnetic confinement assemblies 506, 512. A control signal to the sputter source 504 may be used to adjust the tilt angle and/or the position of the sputter source 504. A control signal to the source magnetic confinement assemblies 520 may be used to adjust the position of the magnetic confinement assemblies relative to the sputter source 504 and/or the magnetic field intensity. Such adjustment of the sputter sources 504 and/or the source magnetic confinement assemblies 520 ensures that the ion beams are shaped and geared towards the first magnetic confinement assembly 506 and/or bottom aperture 514. A control signal to the first and second magnetic confinement assemblies 506 and 512 may be used to adjust the magnetic field intensity and/or position of the assemblies relative to bottom aperture 514, substrate and/or substrate support 514. Such adjustment of the first and second magnetic confinement assemblies 506 and 512 ensures that the combined ion beam 525 is directed towards the localized area of the substrate undergoing combinatorial processing. In other words, the controller may be configured to alter the shape of the ion beams/combined ion beam produced by the sputter sources 504 by adjusting positions of at least one of the source and first and second magnetic assemblies, in response to information about the product being made process performed on a particular location of a wafer supported by the wafer support.

In the drawings, like reference numerals appearing in different drawings represent similar or same components and perform similar or same functions, unless specifically noted otherwise in the description. Furthermore, as would be appreciated by those skilled in the art, according to common practice, the various features of the drawings discussed herein are not necessarily drawn to scale, and that dimensions of various features, structures, or characteristics of the drawings may be expanded or reduced to more clearly illustrate various implementations of the invention described herein.

Implementations of the invention may be described as including a particular feature, structure, or characteristic, but every aspect or implementation may not necessarily include the particular feature, structure, or characteristic. Further, when a particular feature, structure, or characteristic is described in connection with an aspect or implementation, it will be understood that such feature, structure, or characteristic may be included in connection with other implementations, whether or not explicitly described. Thus, various changes and modifications may be made to the provided description without departing from the scope or spirit of the invention. As such, the specification and drawings should be regarded as exemplary only, and the scope of the invention to be determined solely by the appended claims.

What is claimed is:

1. A chamber for combinatorial processing a substrate, comprising:
an enclosure having a bottom;
an aperture defined in the bottom;
an aperture axis of the aperture;
a substrate support disposed below the bottom, wherein the aperture axis is perpendicular to both the aperture and the substrate support;
a first magnetic confinement assembly positioned within the enclosure and above the aperture, the first magnetic confinement assembly operable to move in a vertical direction along the aperture axis;
a second magnetic confinement assembly positioned outside the enclosure and below the substrate support, the second magnetic confinement assembly operable to move in a vertical direction along the aperture axis; and
a plurality of sputter sources located above the aperture and above the first magnetic confinement assembly.

2. The chamber according to claim 1, wherein:
each of the sputter sources has a source magnetic confinement assembly associated therewith and each of the sputter sources having a sputter source axis.

3. The chamber according to claim 2, wherein:
at least one of the source magnetic confinement assemblies is operable to move along the associated sputter source axis.

4. The chamber according to claim 2, wherein:
each source magnetic confinement assembly comprises permanent magnets.

5. The chamber according to claim 2, wherein:
each source magnetic confinement assembly comprises electromagnets.

6. The chamber according to claim 2, further comprising:
a controller configured to alter a shape of a combined ion beam produced by the sputter sources by adjusting positions of at least one of the source magnetic confinement assembly, the first magnetic confinement assembly or the second magnetic confinement assembly.

7. The chamber according to claim 1, wherein the sputter sources are arranged in a tilted configuration, and wherein a tilt angle of the sputter sources is adjustable.

8. The chamber according to claim 2, wherein magnetic fields of the first magnetic confinement assembly and the second magnetic confinement assembly are adjustable.

9. A combinatorial processing chamber, comprising:
an enclosure having an aperture, the aperture being located over a substrate support of the combinatorial processing chamber;
a first magnetic confinement assembly positioned within the enclosure above the aperture, the first magnetic assembly operable to move in a vertical direction within the enclosure; and
a plurality of sputter sources located above the aperture and the first magnetic assembly, each of the plurality of sputter sources having a source magnetic confinement assembly affixed to an outer surface of each of the plurality of sputter sources.

10. The chamber of claim 9, wherein the source magnetic confinement assembly is operable to move along a sputter source axis.

11. The chamber of claim 9, further comprising:
a second magnetic confinement assembly positioned outside the enclosure and below the substrate support, the second magnetic confinement assembly operable to move in a vertical direction along an axis of the aperture.

12. The chamber of claim 11, wherein a magnetic field generated by the first magnetic confinement assembly and the second magnetic confinement assembly is adjustable.

13. The chamber of claim 9, wherein a magnetic field generated by the source magnetic confinement assembly is adjustable.

14. The chamber of claim 9, wherein each of the plurality of sputter sources is moveable, and wherein a bottom surface of each of the plurality of sputter sources is angled relative to a surface of the substrate support.

15. The chamber of claim 9, wherein each source magnetic confinement assembly is affixed outside a plasma loop for each of the plurality of sputter sources.

16. The chamber of claim 9, wherein each of the first magnetic confinement assembly and the source magnetic confinement assembly are annular rings.
